(19) United States
(12) Patent Application Publication
(10) Pub. No.: US 2026/0247691 A1
(43) Pub. Date: Aug. 20, 2026

(54) METAL-SEMICONDUCTOR FIELD-EFFECT TRANSISTORS FOR GALLIUM ARSENIDE TECHNOLOGIES

(71) Applicant: Skyworks Solutions, Inc., Irvine, CA (US)

(72) Inventor: Brian James Johnson, Greensboro, NC (US)

(21) Appl. No.: 19/531,480

(22) Filed: Feb. 5, 2026

Related U.S. Application Data
(60) Provisional application No. 63/759,468, filed on Feb. 17, 2025.

(51) Int. Cl. H10D 84/40; H10D 10/80; H10D 30/01; H10D 30/87; H10D 62/85

(52) U.S. Cl. CPC H10D 84/401; H10D 10/821; H10D 30/0614; H10D 30/87; H10D 62/85

(57) ABSTRACT

Metal-semiconductor field-effect transistors (MESFETs) for gallium arsenide (GaAs) technologies are disclosed herein. In certain embodiments, a semiconductor wafer includes a substrate, a GaAs channel layer formed over the substrate, an etch stop layer formed over the GaAs channel layer, and a GaAs subcollector layer formed over the etch stop layer. The GaAs subcollector layer is patterned to form a source region and a drain region for a GaAs MESFET, as well as a recess between the source region and the drain region. Additionally, a metal gate of the MESFET is formed over the etch stop layer in the recess.

### CROSS-REFERENCE TO RELATED APPLICATIONS

This application claims the benefit of priority under 35 U.S.C. § 119 of U.S. Provisional Patent Application No. 63/759,468, filed Feb. 17, 2025 and titled “METAL-SEMICONDUCTOR FIELD-EFFECT TRANSISTORS FOR GALLIUM ARSENIDE TECHNOLOGIES,” which is herein incorporated by reference in its entirety.

### BACKGROUND

### Field

Embodiments of the invention relate to semiconductor electronics, and in particular to metal-semiconductor field-effect transistors (MESFETs) for gallium arsenide (GaAs) technologies.

### Description of Related Technology

Gallium arsenide (GaAs) heterojunction junction bipolar transistors (HBTs) provide high linearity, efficiency and power density, and thus are suitable for use in a wide range of radio frequency (RF) circuits.

In one example, GaAs HBTs are used to provide amplification in power amplifiers for mobile devices, such as those used in 2G, 3G, 4G (including LTE, LTE-Advanced, and LTE-Advanced Pro), 5G, 6G, WLAN (for instance, WiFi), WPAN (for instance, Bluetooth and ZigBee), WMAN (for instance, WiMax), and/or GPS technologies.

### SUMMARY

In certain embodiments, the present disclosure relates to a semiconductor wafer. The semiconductor wafer includes a substrate, a gallium arsenide channel layer formed over the substrate, an etch stop layer formed over the gallium arsenide channel layer, and a gallium arsenide subcollector layer formed over the etch stop layer. The gallium arsenide subcollector layer is patterned to form a source region and a drain region for a metal-semiconductor field-effect transistor. The semiconductor wafer further includes a recess between the source region and the drain region, and a metal gate of the metal-semiconductor field-effect transistor formed over the etch stop layer in the recess.

In some embodiments, the gallium arsenide subcollector layer is further patterned to form a subcollector region for a heterojunction bipolar transistor. According to a number of embodiments, the semiconductor wafer further includes a metal contact layer formed over the gallium arsenide subcollector layer, the metal contact layer patterned to form a collector contact for the heterojunction bipolar transistor, a source contact for the source region of the metal-semiconductor field-effect transistor, and a drain contact for the drain region of the metal-semiconductor field-effect transistor In accordance with several embodiments, the heterojunction bipolar transistor further includes a collector region formed over the subcollector region, a base region formed over the collector region, and an emitter region formed over the base region. According to various embodiments, the semiconductor wafer further includes an isolation region between the source region of the metal-semiconductor field-effect transistor and the subcollector region of the heterojunction bipolar transistor.

In several embodiments, the etch stop layer includes indium gallium phosphide.

In various embodiments, the etch stop layer includes aluminum gallium arsenide.

In some embodiments, the substrate includes gallium arsenide.

In certain embodiments, a method of semiconductor fabrication is disclosed. The method includes forming a source contact and a drain contact on a gallium arsenide subcollector layer that is over an etch stop layer, the etch stop layer being over a gallium arsenide channel layer, and the gallium arsenide channel layer being over a substrate. The method further includes patterning the gallium arsenide subcollector layer to form a source region and a drain region for a metal-semiconductor field-effect transistor and a recess between the source region and the drain region, the source contact being on the source region, and the drain contact being on the drain region. The method further includes forming a metal gate of the metal-semiconductor field-effect transistor over the etch stop layer in the recess.

In some embodiments, the method further includes patterning the gallium arsenide subcollector layer to form a subcollector region for a heterojunction bipolar transistor. According to a number of embodiments, the method further includes forming the source contact and the drain contact includes forming a metal contact layer formed over the gallium arsenide subcollector layer, and patterning the metal contact layer to form a collector contact for the heterojunction bipolar transistor, the source contact for the source region of the metal-semiconductor field-effect transistor, and the drain contact for the drain region of the metal-semiconductor field-effect transistor. According to a number of embodiments, the method further includes forming a collector region of the heterojunction bipolar transistor over the subcollector region, forming a base region of the heterojunction bipolar transistor over the collector region, and forming an emitter region of the heterojunction bipolar transistor over the base region. In accordance with several embodiments, the method further includes forming an isolation region between the source region of the metal-semiconductor field-effect transistor and the subcollector region of the heterojunction bipolar transistor.

In various embodiments, the etch stop layer includes indium gallium phosphide.

In some embodiments, the etch stop layer includes aluminum gallium arsenide.

In several embodiments, the substrate includes gallium arsenide.

In certain embodiments, the present disclosure relates to a gallium arsenide integrated circuit. The gallium arsenide integrated circuit includes a substrate and a metal-semiconductor field-effect transistor formed over the substrate. The metal-semiconductor field-effect transistor includes a gallium arsenide channel structure over the substrate, an etch stop layer structure over the gallium arsenide channel structure, a source region formed over the etch stop layer structure from a first portion of a gallium arsenide subcollector layer, a drain region formed over the etch stop layer structure from a second portion of the gallium arsenide subcollector layer, and a metal gate formed over the etch stop layer in a recess between the source region and the drain region.

In some embodiments, the gallium arsenide integrated circuit further includes a heterojunction bipolar transistor including a subcollector region formed from a third portion of the gallium arsenide subcollector layer. According to several embodiments, the gallium arsenide integrated circuit further includes a collector contact for the heterojunction bipolar transistor, a source contact for the source region of the metal-semiconductor field-effect transistor, and a drain contact for the drain region of the metal-semiconductor field-effect transistor. In accordance with various embodiments, the heterojunction bipolar transistor further includes a collector region formed over the subcollector region, a base region formed over the collector region, and an emitter region formed over the base region. According to a number of embodiments, the gallium arsenide integrated circuit further includes an isolation region between the source region of the metal-semiconductor field-effect transistor and the subcollector region of the heterojunction bipolar transistor.

In various embodiments, the etch stop layer includes indium gallium phosphide.

In several embodiments, the etch stop layer includes aluminum gallium arsenide.

In a number of embodiments, the substrate includes gallium arsenide.

### BRIEF DESCRIPTION OF THE DRAWINGS

FIG. 1A is a cross-section of one embodiment of a semiconductor wafer prior to fabricating a GaAs MESFET according to one embodiment.

FIG. 1B is a cross-section of one embodiment of a GaAs MESFET fabricated on the semiconductor wafer of FIG. 1A.

FIG. 2A is a cross-section of a semiconductor wafer prior to fabricating GaAs devices according to one embodiment.

FIG. 2B is a cross-section of the semiconductor wafer after an emitter etch according to one embodiment.

FIG. 2C is a cross-section of the semiconductor wafer after a base pedestal etch according to one embodiment.

FIG. 2D is a cross-section of the semiconductor wafer after a collector contact etch according to one embodiment.

FIG. 2E is a cross-section of the semiconductor wafer after contact lithography and metallization according to one embodiment.

FIG. 2F is a cross-section of the semiconductor wafer after a gate layer recess etch according to one embodiment.

FIG. 2G is a cross-section of the semiconductor wafer after gate layer metallization according to one embodiment.

FIG. 3 depicts a cross-section of a semiconductor wafer including a heterojunction bipolar transistor (HBT) and a GaAs MESFET according to one embodiment.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

GaAs is a III-V compound semiconductor providing a number of desirable attributes for fabricating high performance radio frequency (RF) circuits, including microwave electronic circuits. For example, GaAs has a superior electron mobility compared to silicon (Si), thus enabling GaAs transistors to operate at higher frequencies than Si-based transistors. GaAs also operates over a wider temperature range, has lower noise, and/or provides a direct bandgap as compared to Si.

Heterojunction junction bipolar transistor (HBTs) can be fabricated using GaAs technologies to form a wide range of electronic circuits, including, but not limited to, high performance power amplifiers for amplifying RF signals for wireless transmission.

Although GaAs technologies can be used to fabricate excellent HBTs, it is desirable for semiconductor chips fabricated in GaAs technologies to have a robust switching device or switch. For example, in a power amplifier application a switching device can be used to dynamically connect RF power amplifiers to filters, antennas, and/or other RF front-end components. A switching device can also be used to control biasing, load line, impedance matching, and/or other characteristics of an RF power amplifier.

Existing switching solutions for GaAs suffer from various issues, such as poor frequency response and/or high cost.

In a first example, an HBT can simply be used as a switch. Although such an approach is very low cost, an HBT switch has poor OFF-state isolation and thus is difficult to fully turn off. Furthermore, an HBT switch requires continuous power supply in the ON-state, thus degrading power efficiency and/or thermal performance.

In a second example, a high electron mobility transistor (HEMT) can be formed alongside HBT devices. Although HEMTs are very high performance, such an approach is prohibitively expensive due to a need for complex epitaxial structures, additional mask layers, and/or increased topography.

In a third example, a MESFET can be formed from the emitter regions of HBTs using an emitter-MESFET process. Although this approach has low cost, MESFETs fabricated in this manner exhibit poor frequency response due to high parasitic capacitance. Furthermore, to achieve a low-doped layer for the MESFET channel, the doping of the emitter layer is reduced, which leads to the HBTs suffering from high emitter resistance.

MESFETs for GaAs technologies are disclosed herein. In certain embodiments, a semiconductor wafer includes a substrate, a GaAs channel layer formed over the substrate, an etch stop layer formed over the GaAs channel layer, and a GaAs subcollector layer formed over the etch stop layer. The GaAs subcollector layer is patterned to form a source region and a drain region for a GaAs MESFET, as well as a recess between the source region and the drain region. Additionally, a metal gate of the MESFET is formed over the etch stop layer in the recess.

Thus, a MESFET is formed in a GaAs process. Such a MESFET has a much simpler epitaxial structure as compared to a HEMT and thus is much lower cost. Furthermore, a MESFET fabricated in this manner provides better frequency response than MESFETs formed in HBT emitter layers, due to lower parasitic capacitance. Furthermore, the MESFET provides better OFF-state isolation and ON-state performance as compared to using an HBT as a switch.

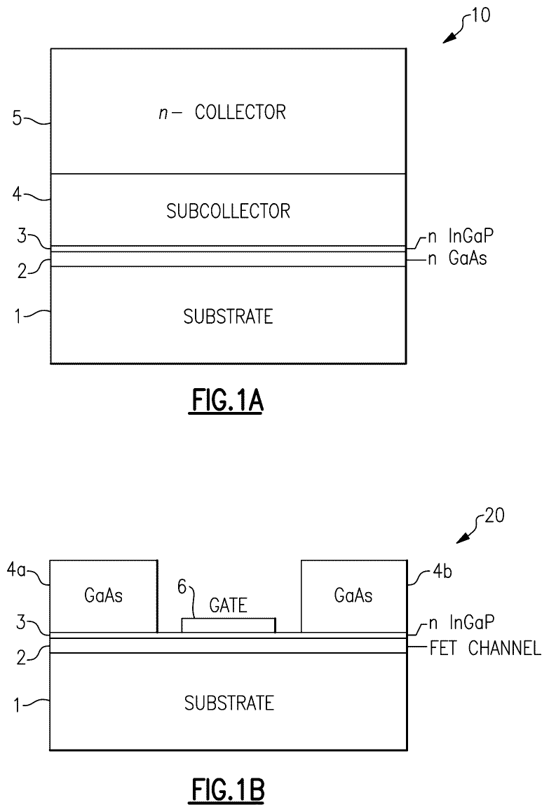

FIG. 1A is a cross-section of one embodiment of a semiconductor wafer 10 prior to fabricating a GaAs MESFET according to one embodiment. The semiconductor wafer 10 includes a substrate 1, a GaAs channel layer 2, an indium gallium phosphide (InGaP) etch stop layer 3, a GaAs subcollector layer 4, and a GaAs collector layer 5.

In the illustrated embodiment, the semiconductor wafer 10 includes an epitaxial structure that is formed over the substrate 1. In some implementations, the substrate 1 is a GaAs substrate. However, other implementations are possible, such as configurations using silicon-based substrates, such as silicon (Si) or silicon carbide (SiC). The epitaxial structure includes the GaAs channel layer 2 that is epitaxially grown over the substrate 1. The epitaxial structure further includes the InGaP etch stop layer 3 over the GaAs channel layer 2, the GaAs subcollector layer 4 over the InGaP etch stop layer 3, and the GaAs collector layer 5 over the GaAs subcollector layer 4.

Although various layers are depicted in FIG. 1A, additional layers can be included over the semiconductor wafer 10, such as those associated with base and emitter regions of HBTs.

With continuing reference to FIG. 1A, rather than directly including the GaAs subcollector layer 4 over the substrate 1, the semiconductor wafer 10 includes the addition of the GaAs channel layer 2 and the InGaP etch stop layer 3 between the substrate 1 and the GaAs subcollector layer 4. In the illustrated embodiment, the GaAs channel layer 2 and the InGaP etch stop layer 3 are doped n-type. However, the teachings herein are applicable to other doping types (for instance, p-type) and/or to etch stop layers implemented using other materials. For example, in another embodiment, the etch stop layer 3 includes aluminum gallium arsenide (AlGaAs) or another suitable etch stop material.

The addition of the GaAs channel layer 2 and the InGaP etch stop layer 3 allows for the fabrication of MESFETs alongside of HBT transistors that utilize the collector layer 5 and the subcollector layer 4 for HBT collector formation.

FIG. 1B is a cross-section of one embodiment of a GaAs MESFET 20 fabricated on the semiconductor wafer 10 of FIG. 1A.

As shown in FIG. 1B, a portion of the GaAs channel layer 2 has been used to form a channel of the GaAs MESFET 20. Additionally, a first portion of the GaAs subcollector layer 4 has been patterned to form a GaAs source region 4a, while a second portion of the GaAs subcollector layer 4 has been patterned to form a GaAs drain region 4b. Furthermore, a metal gate region 6 has been formed over the InGaP etch stop layer 3 in a recess between the GaAs source region 4a and the GaAs drain region 4b. The metal gate region 6 serves as a gate of the GaAs MESFET 20.

With reference to FIGS. 1A and 1B, the inclusion of the GaAs channel layer 2 and the InGaP etch stop layer 3 between the substrate 1 and the GaAs subcollector layer 4 allows for the formation of relatively high-performance GaAs MESFETs at low cost.

For example, the semiconductor wafer 10 allows for formation of the GaAs MESFET 20 with a much simpler epitaxial structure as compared to a GaAs process for fabricating both HEMTs alongside HBTs. The simpler epitaxial structure allows for reduced fabrication complexity and much lower cost. Moreover, forming GaAs MESFETs in this manner has a lower starting wafer cost relative to a HEMT process.

Furthermore, by fabricating the GaAs MESFET 20 in this manner improved frequency response is achieved relative to forming a GaAs MESFET from HBT emitter layers. For example, such an improved frequency response can arise from lower parasitic capacitance and/or lower resistivity of the GaAs subcollector layer 4 relative to an emitter layer, which is doped more lightly than the GaAs subcollector layer 4. Moreover, the GaAs MESFET 20 provides better OFF-state isolation as compared to simply using an HBT as a switch. Additionally, the GaAs MESFET 20 advantageously operates with a near zero ON-state power draw and thus exhibits lower power dissipation and superior thermal performance characteristics as compared to HBT switches.

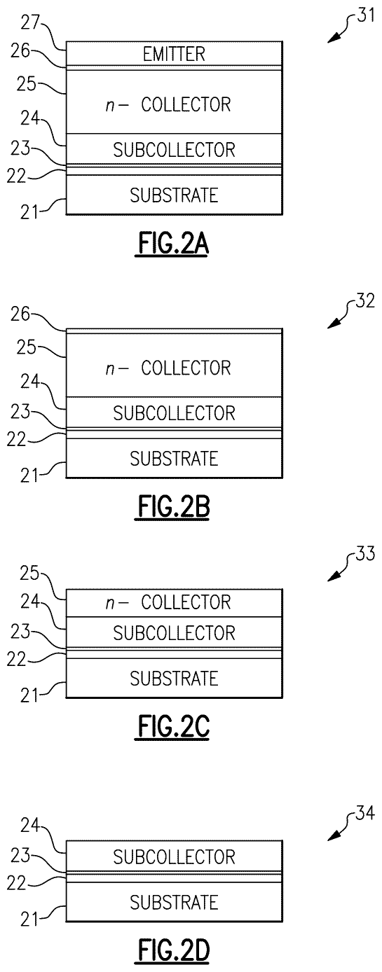

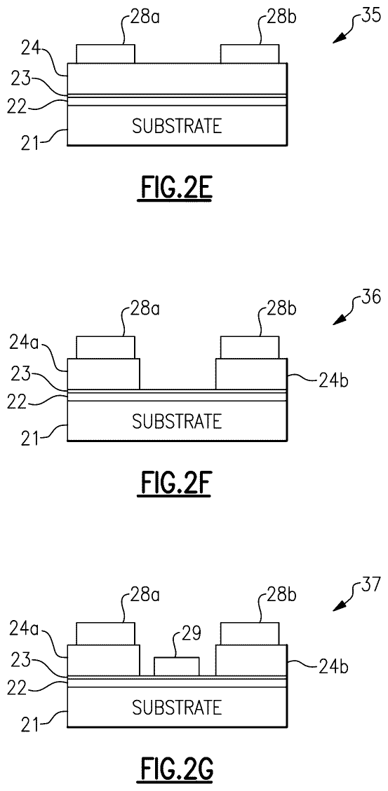

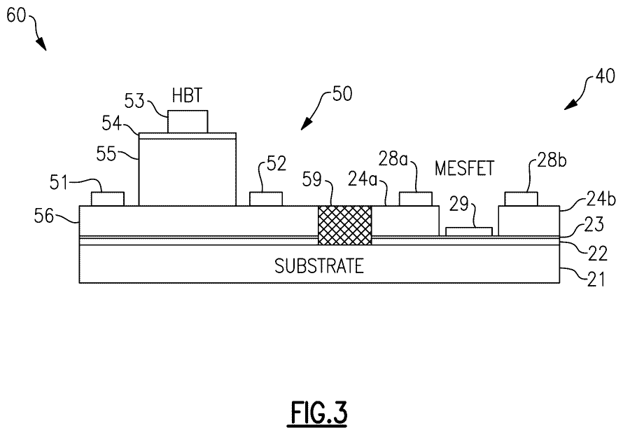

FIG. 2A is a cross-section of a semiconductor wafer 31 prior to fabricating GaAs devices according to one embodiment.

As shown in FIG. 2A, the semiconductor wafer 31 includes a substrate 21 (GaAs, in this example), a GaAs channel layer 22, a subcollector etch stop layer 23 (for instance, InGaP), a GaAs subcollector layer 24, a GaAs collector layer 25, a base layer 26 (for instance, GaAs), and an emitter layer 27 (for instance, InGaP).

In FIG. 2A, only a portion of the semiconductor wafer 31 associated with fabricating one example GaAs MESFET is shown. As depicted in FIGS. 2B to 2G, the semiconductor wafer 31 is subsequently processed to form the example GaAs MESFET.

However, one or more HBTs are simultaneously formed alongside the GaAs MESFET (as shown for example in FIG. 3) using common processing steps. Thus, skilled artisans will appreciate that HBTs and GaAs MESFETs are simultaneously fabricated alongside one another on the semiconductor wafer 31, and thus other devices are simultaneously formed during the depicted processing steps.

FIG. 2B is a cross-section of the semiconductor wafer 32 after an emitter etch according to one embodiment. The emitter etch is associated with patterning the emitter layer 27 of FIG. 2A to remove a portion of the emitter layer 27 where the GaAs MESFET is to be formed. Such an emitter etch is used to pattern emitter mesas and/or other emitter structures for HBTs elsewhere on the wafer.

Although shown as a single layer, the emitter layer 27 can include sub-layers. In one example, the emitter layer 27 includes an n InGaP emitter layer formed over a p+ GaAs base layer 26, an n+ GaAs emitter cap layer formed over the n InGaP emitter layer, and an n++ InGaAs emitter contact layer formed over the n+ GaAs emitter cap layer.

FIG. 2C is a cross-section of the semiconductor wafer 33 after a base pedestal etch according to one embodiment. The base pedestal etch is associated with patterning the base layer 26 and an upper portion of the collector layer 25 to form base pedestals for HBTs. The base layer 26 and the upper portion of the collector layer 25 is removed where the GaAs MESFET is to be formed.

FIG. 2D is a cross-section of the semiconductor wafer 34 after a collector contact etch according to one embodiment. The collector layer 25 is etched to provide openings for collector metal contact formation for HBTs. The collector contact etch can be, for example, a timed etch to stop at a top of the subcollector layer 24.

FIG. 2E is a cross-section of the semiconductor wafer 35 after contact lithography and metallization according to one embodiment. As shown in FIG. 2E, contact lithography and metallization is used to form a source metal contact 28a and a drain metal contact 28b for the GaAs MESFET. Contact lithography and metallization is also used to form collector metal contacts for HBTs (not shown in FIG. 2E).

FIG. 2F is a cross-section of the semiconductor wafer 36 after a gate layer recess etch according to one embodiment. As shown in FIG. 2F, the gate layer recess etch is used to pattern the subcollector layer 24 to form a source region 24a for the GaAs MESFET and a drain region 24b for the GaAs MESFET. Additionally, a portion of the subcollector layer 24 between the source region 24a and the drain region 24b is etched to form a recess where a metal gate of the GaAs MESFET is to be formed. The gate layer recess etch is stopped by the subcollector etch stop layer 23, in this example.

FIG. 2G is a cross-section of the semiconductor wafer 37 after gate layer metallization according to one embodiment. The gate layer metallization has been used to form a metal gate region 29 for the resulting GaAs MESFET. As shown in FIG. 2G, the metal gate region 29 is formed in the recess between the source region 24a and the drain region 24b.

FIG. 3 depicts a cross-section of a semiconductor wafer 60 including an HBT 50 and a GaAs MESFET 40 according to one embodiment.

The semiconductor wafer 60 can initially include an epitaxial structure similar to that of the semiconductor wafer 31 of FIG. 2A. The semiconductor wafer 60 is subsequently processed using a processing flow similar to that of FIGS. 2B to 2G to simultaneously form both the HBT 50 and the GaAs MESFET 40 alongside one another. The processing flow for the semiconductor wafer 60 includes a base etch for etching the collector layer, for instance, a timed etch to stop at the top of the subcollector layer. The base pedestal etch can include etching through the base and at least a portion of the collector layer to form a pedestal rising up from the subcollector epitaxial layer.

In the illustrated embodiment, the GaAs channel layer 22 forms a channel for the GaAs MESFET 40. A portion of the subcollector etch stop layer 23 (for example, InGaP) also remains over the MESFET's channel. The GaAs MESFET 40 also includes a GaAs source region 24a, a GaAs drain region 24b, and a metal gate region 29 formed over the GaAs channel layer 22/etch stop layer 23 in the recess between the GaAs source region 24a and the GaAs drain region 24b. Additionally, a source metal contact 28a has been formed to contact the GaAs source region 24a, while a drain metal contact 28b has been formed to contact the GaAs drain region 24.

With continuing reference to FIG. 3, the HBT 50 includes metal contacts 51/52 over the subcollector region 56, a collector pedestal region 55 over the subcollector region 56, a base pedestal region 54 over the collector pedestal region 55, and an emitter region 53 over the base pedestal region 54.

In the illustrated embodiment, a relatively high-performance GaAs MESFET 40 has been formed alongside the HBT 50 using low-cost processing.

As shown in FIG. 3, the GaAs MESFET 40 is isolated from the HBT 50 using isolation 59. The isolation 59 extends from the top of the subcollector layer to the substrate 21, in this embodiment. The isolation 59 can correspond to any type of isolation structure including, but not limited to, implant isolation and/or trench isolation, such as shallow trench isolation (STI).

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above detailed description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A semiconductor wafer comprising:
a substrate;
a gallium arsenide channel layer formed over the substrate;
an etch stop layer formed over the gallium arsenide channel layer; and
a gallium arsenide subcollector layer formed over the etch stop layer, the gallium arsenide subcollector layer patterned to form a source region and a drain region for a metal-semiconductor field-effect transistor, and a recess between the source region and the drain region; and
a metal gate of the metal-semiconductor field-effect transistor formed over the etch stop layer in the recess.

2. The semiconductor wafer of claim 1 wherein the gallium arsenide subcollector layer is further patterned to form a subcollector region for a heterojunction bipolar transistor.

3. The semiconductor wafer of claim 2 further comprising a metal contact layer formed over the gallium arsenide subcollector layer, the metal contact layer patterned to form a collector contact for the heterojunction bipolar transistor, a source contact for the source region of the metal-semiconductor field-effect transistor, and a drain contact for the drain region of the metal-semiconductor field-effect transistor.

4. The semiconductor wafer of claim 2 wherein the heterojunction bipolar transistor further includes a collector region formed over the subcollector region, a base region formed over the collector region, and an emitter region formed over the base region.

5. The semiconductor wafer of claim 2 further comprising an isolation region between the source region of the metal-semiconductor field-effect transistor and the subcollector region of the heterojunction bipolar transistor.

6. The semiconductor wafer of claim 1 wherein the etch stop layer includes indium gallium phosphide.

7. The semiconductor wafer of claim 1 wherein the etch stop layer includes aluminum gallium arsenide.

8. The semiconductor wafer of claim 1 wherein the substrate includes gallium arsenide.

9. A method of semiconductor fabrication, the method comprising:
forming a source contact and a drain contact on a gallium arsenide subcollector layer that is over an etch stop layer, the etch stop layer being over a gallium arsenide channel layer, and the gallium arsenide channel layer being over a substrate;
patterning the gallium arsenide subcollector layer to form a source region and a drain region for a metal-semiconductor field-effect transistor and a recess between the source region and the drain region, the source contact being on the source region and the drain contact being on the drain region; and
forming a metal gate of the metal-semiconductor field-effect transistor over the etch stop layer in the recess.

10. The method of claim 9 further comprising patterning the gallium arsenide subcollector layer to form a subcollector region for a heterojunction bipolar transistor.

11. The method of claim 10 wherein forming the source contact and the drain contact includes forming a metal contact layer formed over the gallium arsenide subcollector layer, and patterning the metal contact layer to form a collector contact for the heterojunction bipolar transistor, the source contact for the source region of the metal-semiconductor field-effect transistor, and the drain contact for the drain region of the metal-semiconductor field-effect transistor.

12. The method of claim 10 further comprising forming a collector region of the heterojunction bipolar transistor over the subcollector region, forming a base region of the heterojunction bipolar transistor over the collector region, and forming an emitter region of the heterojunction bipolar transistor over the base region.

13. The method of claim 10 further comprising forming an isolation region between the source region of the metal-semiconductor field-effect transistor and the subcollector region of the heterojunction bipolar transistor.

14. The method of claim 9 wherein the etch stop layer includes indium gallium phosphide.

15. The method of claim 9 wherein the etch stop layer includes aluminum gallium arsenide.

16. A gallium arsenide integrated circuit comprising:
a substrate; and
a metal-semiconductor field-effect transistor formed over the substrate, the metal-semiconductor field-effect transistor including a gallium arsenide channel structure over the substrate, an etch stop layer structure over the gallium arsenide channel structure, a source region formed over the etch stop layer structure from a first portion of a gallium arsenide subcollector layer, a drain region formed over the etch stop layer structure from a second portion of the gallium arsenide subcollector layer, and a metal gate formed over the etch stop layer in a recess between the source region and the drain region.

17. The gallium arsenide integrated circuit of claim 16 further comprising a heterojunction bipolar transistor including a subcollector region formed from a third portion of the gallium arsenide subcollector layer.

18. The gallium arsenide integrated circuit of claim 17 further comprising a collector contact for the heterojunction bipolar transistor, a source contact for the source region of the metal-semiconductor field-effect transistor, and a drain contact for the drain region of the metal-semiconductor field-effect transistor.

19. The gallium arsenide integrated circuit of claim 17 wherein the heterojunction bipolar transistor further includes a collector region formed over the subcollector region, a base region formed over the collector region, and an emitter region formed over the base region.

20. The gallium arsenide integrated circuit of claim 17 further comprising an isolation region between the source region of the metal-semiconductor field-effect transistor and the subcollector region of the heterojunction bipolar transistor.
